(19) United States
(12) Patent Application Publication
(10) Pub. No.: US 2026/0130065 A1
(43) Pub. Date: May 7, 2026

(54) DISPLAY PANEL AND ELECTRONIC DEVICE INCLUDING THE SAME

(71) Applicant: Samsung Display Co., LTD., Yongin-si (KR)

(72) Inventors: SUN-KYO JUNG, Yongin-si (KR); HOSUNG SONG, Yongin-si (KR); SUNG-MIN CHO, Yongin-si (KR)

(21) Appl. No.: 19/225,057

(22) Filed: Jun. 2, 2025

(30) Foreign Application Priority Data
Nov. 1, 2024 (KR) 10-2024-0153833

(51) Int. Cl. H10K 59/124; H10K 59/131

(52) U.S. Cl. CPC H10K 59/124; H10K 59/131

(57) ABSTRACT

A display panel includes a base substrate, a semiconductor pattern, an insulating layer, a gate pattern, an inter-insulating layer, a source-drain pattern, a via layer, and a light-emitting diode. The base substrate includes a first region and a second region including a bending region which is bendable, a cover region extending from one side of the bending region and surrounds the first region, and a pad region extending from an opposite side of the bending region. The semiconductor pattern on the first region includes a semiconductor material. The insulating layer on the base substrate covers the semiconductor pattern. The gate pattern on the gate insulating layer at least partially overlaps the semiconductor pattern. The insulating layer covers the gate pattern. First crack-prevention openings and second crack-prevention openings are defined in the insulating layer. The number of the first crack-prevention openings is different from the number of the second crack-prevention openings.

This application claims priority to Korean Patent Application No. 10-2024-0153833, filed on Nov. 1, 2024, and all the benefits accruing therefrom under 35 U.S.C. § 119, the content of which in its entirety is herein incorporated by reference.

### BACKGROUND

### 1. Field

The disclosure relates to a display panel configured for preventing defects caused by crack propagation, and an electronic device including the same.

### 2. Description of the Related Art

A display panel and an electronic device containing the display panel typically include a plurality of light-emitting diodes to provide images to users. Additionally, wiring for controlling the plurality of light-emitting diodes is arranged on the display panel.

### SUMMARY

During the usage of an electronic device by the user, various forms of impact may be exerted to the display panel. Consequently, cracks may occur in the display panel, and if the cracks propagate to the aforementioned wiring, the wiring may become exposed externally. The exposed wiring is susceptible to corrosion, and such corrosion may lead to malfunction of the display panel.

Particularly, when cracks occur in areas where more wiring is concentrated, the likelihood of failure due to crack propagation increases. The vulnerability of the display panel to crack propagation-induced failure may vary depending on the specific regions of the display panel.

A feature of the disclosure is to provide a display panel and an electronic device having the same, capable of effectively preventing defects caused by crack propagation by designing crack dams in a differentiated manner depending on the region.

A display panel in an embodiment of the disclosure may include a base substrate, a semiconductor pattern, a gate insulating layer, a gate pattern, an inter-insulating layer, a source-drain pattern, a via layer, and a light-emitting diode. The base substrate may have a first region and a second region defined therein. The second region may include a bending region, a cover region, and a pad region. The bending region may be bendable. The cover region may extend from one side of the bending region and surround the first region. The pad region may extend from the opposite side of the bending region. The semiconductor pattern may be disposed on the first region and may include a semiconductor material. The gate insulating layer may be disposed on the base substrate and may cover the semiconductor pattern. The gate pattern may be disposed on the gate insulating layer, with at least a portion thereof overlapping the semiconductor pattern. The inter-insulating layer may cover the gate pattern. A plurality of first crack-prevention openings defined in a portion of the inter-insulating layer overlapping the cover region and a plurality of second crack-prevention openings defined in a portion of the inter-insulating layer overlapping the pad region. Each of the plurality of first crack-prevention openings may extend along an outer edge of the cover region, and each of the plurality of second crack-prevention openings may extend along an outer edge of the pad region. The number of the plurality of first crack-prevention openings and the number of the plurality of second crack-prevention openings may differ from each other. The source-drain pattern may be disposed on the inter-insulating layer, with at least a portion thereof electrically connected to the semiconductor pattern. The via layer may cover the source-drain pattern, and the light-emitting diode may be disposed on the via layer.

In an embodiment of the disclosure, the number of the plurality of second crack-prevention openings may be greater than the number of the plurality of first crack-prevention openings.

In an embodiment of the disclosure, at least one of a plurality of third crack-prevention openings and a plurality of fourth crack-prevention openings may be defined in the gate insulating layer. The plurality of third crack-prevention openings may overlap the first crack-prevention openings, respectively. The plurality of fourth crack-prevention openings may overlap the second crack-prevention openings, respectively.

A display panel in an embodiment of the disclosure may further include a plurality of pads, an electrical component, and a plurality of spider wirings. The plurality of pads may be arranged on the pad region. The electrical component may overlap the plurality of pads. Each of the plurality of spider wirings may extend, respectively, from the pads and transfer signals from the electrical component to at least one of the source-drain pattern and the gate pattern. The plurality of second crack-prevention openings may be defined between the plurality of spider wirings and the outer edge of the pad region.

In an embodiment of the disclosure, the plurality of second crack-prevention openings may be spaced apart from the plurality of first crack-prevention openings across the bending region in a plan view.

In an embodiment of the disclosure, when the bending region is bent, the plurality of second crack-prevention openings may overlap with at least one of the first region and the cover region.

In an embodiment of the disclosure, the base substrate may include a first base layer, a second base layer, and a third base layer. The first base layer may include an organic material. The second base layer may be disposed on the first base layer. At least one of a plurality of fifth crack-prevention openings and a plurality of sixth crack-prevention openings may be defined in the second base layer. The plurality of fifth crack-prevention openings may overlap with the plurality of first crack-prevention openings, respectively. The plurality of sixth crack-prevention openings may overlap with the plurality of second crack-prevention openings, respectively. The third base layer may be disposed on the second base layer. The third base layer may include an organic material.

In an embodiment of the disclosure, a shape formed by projecting each of the plurality of second crack-prevention openings onto the base substrate may include at least one of a line shape, a curve shape, and a zigzag shape.

The display panel in an embodiment of the disclosure may further include a functional layer, which may be disposed between the base substrate and the semiconductor pattern. At least one of a plurality of seventh crack-prevention openings and a plurality of eighth crack-prevention openings may be defined in the functional layer. The plurality of seventh crack-prevention openings may overlap with the plurality of first crack-prevention openings, respectively. The plurality of eighth crack-prevention openings may overlap with the plurality of second crack-prevention openings, respectively.

A display panel in another embodiment of the disclosure may include a base substrate, a semiconductor pattern, a gate insulating layer, a gate pattern, an inter-insulating layer, a source-drain pattern, a via layer, and a light-emitting diode. The base substrate may have a first region and a second region defined therein. The second region may include a bending region, a cover region, and a pad region. The bending region may be bendable. The cover region may extend from one side of the bending region and may surround the first region. The pad region may extend from the opposite side of the bending region. The semiconductor pattern may be disposed on the first region and may include a semiconductor material. The gate insulating layer may be disposed on the base substrate and may cover the semiconductor pattern. The gate pattern may be disposed on the gate insulating layer, with at least a portion thereof overlapping the semiconductor pattern. The inter-insulating layer may be disposed to overlap the first region and may cover the gate pattern. The inter-insulating layer may include a plurality of first protruding members and a plurality of second protruding members. The plurality of first protruding members may be arranged to be spaced apart from each other on the cover region. The plurality of second protruding members may be arranged to be spaced apart from each other on the pad region. Each of the first protruding members may extend along at least a portion of an outer boundary of the cover region. Each of the second protruding members may extend along at least a portion of an outer boundary of the pad region. The source-drain pattern may be disposed on the inter-insulating layer, with at least a portion thereof electrically connected to the semiconductor pattern. The via layer may cover the source-drain pattern, and the light-emitting diode may be disposed on the via layer. The number of the first protruding members and the number of the second protruding members may differ from each other.

In an embodiment of the disclosure, the number of the second protruding members may be greater than the number of the first protruding members.

In an embodiment of the disclosure, the gate insulating layer may include at least one of a plurality of third protruding members and a plurality of fourth protruding members. The third protruding members may overlap the first protruding members, respectively. The fourth protruding members may overlap the second protruding members, respectively.

The display panel in another embodiment of the disclosure may further include a plurality of pads, an electrical component, and a plurality of spider wirings. The plurality of pads may be arranged on the pad region. The electrical component may be electrically connected to the plurality of pads. The plurality of spider wirings may extend, respectively, from the plurality of pads and deliver signals provided by the electrical component to at least one of the source-drain pattern and the gate pattern. The plurality of second protruding members may be disposed between the plurality of spider wirings and the outer edge of the pad region.

In an embodiment of the disclosure, the second protruding members may be spaced apart from the first protruding members across the bending region in a plan view.

In an embodiment of the disclosure, when the bending region is bent, the second protruding members may overlap at least one of the first region and the cover region.

In an embodiment of the disclosure, the base substrate may include a first base layer, a second base layer, and a third base layer. The first base layer may include an organic material. The second base layer may be disposed on the first base layer. The second base layer may include at least one of a plurality of fifth protruding members and a plurality of sixth protruding members. The fifth protruding members may overlap the first protruding members, respectively. The sixth protruding members may overlap the second protruding members, respectively. The third base layer may be disposed on the second base layer and may include an organic material.

In an embodiment of the disclosure, a shape formed by projecting each of the plurality of second protruding members onto the base substrate may include at least one of a line shape, a curve shape, and a zigzag shape.

The display panel in an embodiment of the disclosure may further include a functional layer disposed between the base substrate and the semiconductor pattern. The functional layer may include at least one of a plurality of seventh protruding members and a plurality of eighth protruding members. The seventh protruding members may overlap the first protruding members, respectively. The eighth protruding members may overlap the second protruding members, respectively.

An electronic device in an embodiment of the disclosure may include a display panel. The display panel may include a base substrate, a semiconductor pattern, a gate insulating layer, a gate pattern, an inter-insulating layer, a source-drain pattern, a via layer, and a light-emitting diode. The base substrate may have a first region and a second region defined therein. The second region may include a bending region, a cover region, and a pad region. The bending region may be bendable. The cover region may extend from one side of the bending region and may surround the first region. The pad region may extend from the opposite side of the bending region. The semiconductor pattern may be disposed in the first region and may include a semiconductor material. The gate insulating layer may be disposed on the base substrate and may cover the semiconductor pattern. The gate pattern may be disposed on the gate insulating layer, with at least a portion thereof overlapping the semiconductor pattern. The inter-insulating layer may be disposed to overlap the first region and may cover the gate pattern. The inter-insulating layer may include a plurality of first protruding members and a plurality of second protruding members. The plurality of first protruding members may be arranged to be spaced apart from each other on the cover region. The plurality of second protruding members may be arranged to be spaced apart from each other on the pad region. Each of the plurality of first protruding members may extend along at least a portion of an outer boundary of the cover region. Each of the plurality of second protruding members may extend along at least a portion of an outer boundary of the pad region. The source-drain pattern may be disposed on the inter-insulating layer, with at least a portion thereof electrically connected to the semiconductor pattern. The via layer may cover the source-drain pattern. The light-emitting diode may be disposed on the via layer. The number of the first protruding members and the number of the second protruding members may differ from each other.

In an embodiment of the disclosure, a plurality of first crack-prevention openings may be defined in a portion of the inter-insulating layer overlapping the cover region. Each of the plurality of first crack-prevention openings may extend along an outer edge of the cover region. A plurality of second crack-prevention openings may be defined in a portion of the inter-insulating layer overlapping the pad region. Each of the plurality of second crack-prevention openings may extend along an outer edge of the pad region. The number of the first crack-prevention openings and the number of the second crack-prevention openings may differ from each other.

By embodiments of the disclosure, it is possible to provide a display panel, and an electronic device including the same, which may effectively prevent defects caused by crack propagation, owing to designing crack dams in a differentiated manner according to the regions.

### BRIEF DESCRIPTION OF THE DRAWINGS

These and/or other features will become apparent and more readily appreciated from the following description of the embodiments, taken in conjunction with the accompanying drawings in which:

FIGS. 1A and 1B are a perspective view and an exploded view illustrating an embodiment of an electronic device according to the disclosure;

FIG. 2A is a plan view illustrating a display panel;

FIG. 2B illustrates an example where the bending region is bent;

FIG. 2C is a cross-sectional view of the display panel taken along line I-I′ of FIG. 2A;

FIG. 2D is an enlarged view of a portion of the display panel shown in FIG. 2A;

FIG. 2E is a cross-sectional view of the cover region taken along line II-II′ of FIG. 2A;

FIG. 2F is a cross-sectional view of the pad region taken along line III-III′ of FIG. 2D;

FIGS. 3A, 3C, and 3E are cross-sectional views illustrating the cover region taken along line II-II′ of FIG. 2A;

FIGS. 3B, 3D, and 3F are cross-sectional views illustrating the pad region taken along line III-III′ of FIG. 2D;

FIG. 3G is a cross-sectional view illustrating a section of the cover region taken along line II-II′ of FIG. 2A, and FIG. 3H is a cross-sectional view illustrating a section of the pad region taken along line III-III′ of FIG. 2D;

FIGS. 4A, 4B, 4C, 4D, and 4E are enlarged views of a portion of the second region shown in FIG. 2A;

FIG. 5A illustrates a block diagram of an embodiment of an electronic device according to the disclosure; and

FIG. 5B illustrates an embodiment of various electronic devices according to the disclosure.

### DETAILED DESCRIPTION

References will now be made in detail to illustrative embodiments, of which examples are illustrated in the accompanying drawings, where like reference numerals refer to like elements throughout. The embodiments may have a variety of forms and permutations, but the disclosure shall by no means be construed as being limited to the described embodiments. Rather, the disclosure shall be construed to encompass all forms, permutations, equivalents and substitutes covered by the technical ideas and scope of the disclosure. Accordingly, the embodiments are merely described below, by referring to the drawing figures, to explain features of the disclosure.

Like or identical reference numerals refer to like or identical elements. Moreover, in the accompanying drawings, the thicknesses, ratios, and dimensions of the elements may not be to exact scale and may have been exaggerated for priority to effective explanation of the technical features associated with these elements. As such, the disclosure shall not be restricted to the thicknesses, ratios, dimensions, etc. Illustrated in the drawings. The term “and/or” shall include the combination of a plurality of listed items or any of the plurality of listed items that may be defined by relevant elements.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

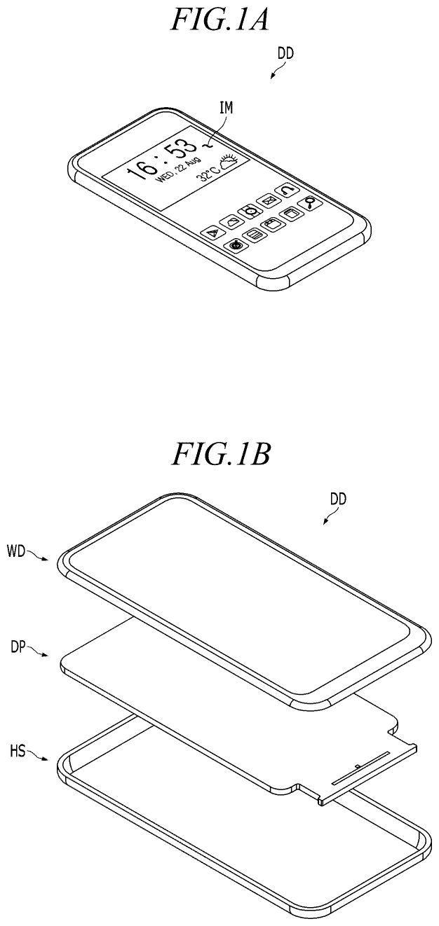

FIG. 1A is a perspective view illustrating an embodiment of an electronic device DD according to the disclosure, and FIG. 1B is an exploded view illustrating the electronic device DD.

Referring to FIGS. 1A and 1B, the electronic device DD may include a window WD, a display panel DP, and a housing HS. The electronic device DD may provide an image IM to a user. In an embodiment, the electronic device DD may be any one of a monitor, television, smartphone, wearable device, navigation device, in-vehicle terminal, or tablet personal computer PC. However, the shape and use of the electronic device DD are not limited to the aforementioned examples as long as the electronic device DD is capable of providing an image IM.

The window WD may be disposed on the display panel DP to define the exterior of the electronic device DD and protect the display panel DP. The display panel DP may provide an image IM to a user. The housing HS may accommodate and protect the display panel DP.

Although not shown, the electronic device DD may further include an input detection circuit disposed between the display panel DP and the window WD. The input detection circuit may detect user input, such as touch, and may include a plurality of input detection sensors. In an embodiment of the disclosure, at least one of the window WD and the housing HS may be omitted.

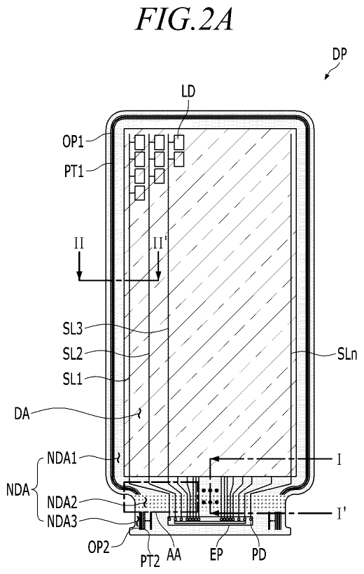

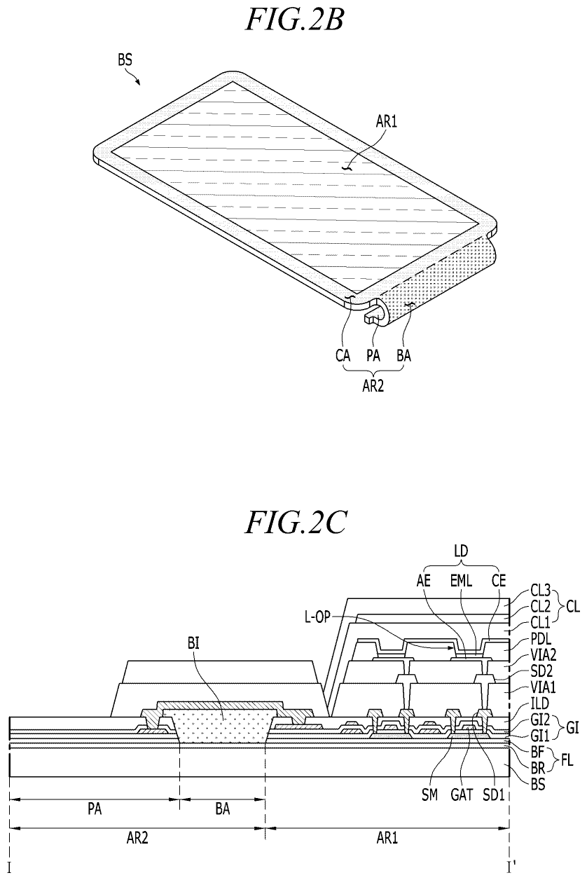

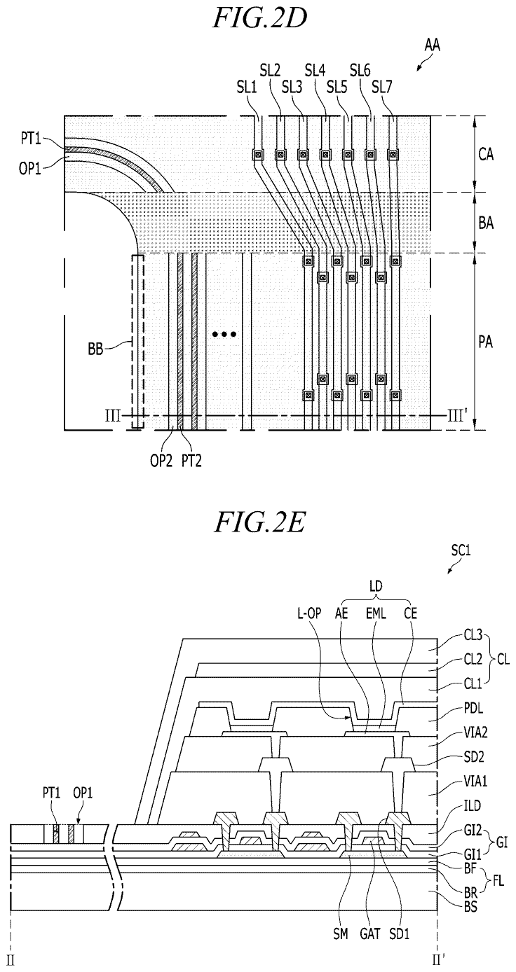

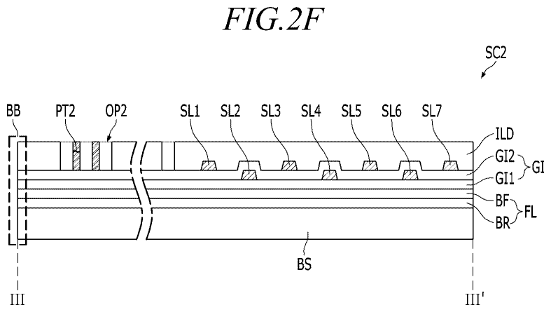

FIG. 2A is a plan view illustrating a display panel DP shown in FIG. 1B. FIG. 2B illustrates an example where a bending region BA of a base substrate BS in an embodiment of the disclosure is bent. FIG. 2C is a cross-sectional view of the display panel DP taken along line I-I′ of FIG. 2A.

Referring to FIGS. 2A to 2C, the display panel DP may have a display region DA and a non-display region NDA defined therein. A plurality of light-emitting diodes LD may be disposed on the display region DA. The non-display region NDA may surround the display region DA and may include a first non-display region NDA1, a second non-display region NDA2, and a third non-display region NDA3.

The display panel DP may include the base substrate BS, a semiconductor pattern SM, a functional layer FL, a gate insulating layer GI, a gate pattern GAT, an inter-insulating layer ILD, a first source-drain pattern SD1, a first via layer VIA1, a second source-drain pattern SD2, a second via layer VIA2, a pixel defining layer PDL, the light-emitting diodes LD, an encapsulation layer CL, a bending insulating layer BI, a plurality of pads PD, an electrical component EP, and a plurality of spider wirings SL1 to SLn (n is a natural number greater than 1).

A first region AR1 and a second region AR2 may be defined in the base substrate BS. The first region AR1 of the base substrate BS may correspond to the display region DA of the display panel DP, while the second region AR2 of the base substrate BS may correspond to the non-display region NDA of the display panel DP.

The first region AR1 overlaps an area where an image IM is provided, and a plurality of light-emitting diodes LD may be disposed on the first region AR1. The second region AR2 may include a cover region CA, the bending region BA, and a pad region PA. The cover region CA may correspond to the first non-display region NDA1, the bending region BA may correspond to the second non-display region NDA2, and the pad region PA may correspond to the third non-display region NDA3.

The cover region CA may extend from one side of the bending region BA and may surround the first region AR1. The bending region BA may be bendable. The pad region PA may extend from the opposite side of the bending region BA.

The semiconductor pattern SM may be disposed on the first region AR1 and may include a semiconductor material. In an embodiment of the disclosure, the semiconductor material may include at least one of an amorphous silicon semiconductor, a polycrystalline silicon semiconductor, a metal oxide semiconductor, a crystalline oxide semiconductor, and an amorphous oxide semiconductor. In an embodiment, the oxide semiconductor may include at least one of indium-tin oxide (“ITO”), indium-gallium-zinc oxide (“IGZO”), zinc oxide (ZnO), indium-zinc oxide (IZnO), zinc-indium oxide (“ZIO”), indium oxide (InO), titanium oxide (TiO), indium-zinc-tin oxide (“IZTO”), and zinc-tin oxide (“ZTO”).

The functional layer FL may be disposed between the base substrate BS and the semiconductor pattern SM. The functional layer FL may include at least one of a buffer layer BF and a barrier layer BR. In an embodiment of the disclosure, the functional layer FL may be omitted.

The buffer layer BF may include at least one of an inorganic material and an organic material. In an embodiment, the buffer layer BF may include at least one of silicon nitride, silicon oxynitride, silicon oxide, titanium oxide, aluminum oxide, and acrylic-based organic materials.

The barrier layer BR may prevent foreign substances from diffusing into the semiconductor pattern SM. In an embodiment, the barrier layer BR may include at least one of indium-zinc oxide, gallium-zinc oxide, and aluminum-zinc oxide.

The gate insulating layer GI may be disposed on the base substrate BS and may cover the semiconductor pattern SM. The gate insulating layer GI may include at least one of an organic insulating material and an inorganic insulating material. In an embodiment, the gate insulating layer GI may include at least one of polysiloxane, silicon nitride, silicon oxide, silicon oxynitride, polyacrylic compounds, polyimide compounds, fluorinated carbon compounds, and benzocyclobutene compounds.

In an embodiment of the disclosure, the gate insulating layer GI may include different layers, such as a first gate insulating layer GI1 and a second gate insulating layer GI2. However, the gate insulating layer GI is not limited thereto and may further include at least one additional layer including or consisting of insulating material.

The gate pattern GAT may be disposed on the gate insulating layer GI, and at least a portion of the gate pattern GAT may overlap the semiconductor pattern SM. The gate pattern GAT may include a metal material. In an embodiment, the gate pattern GAT may include at least one of gold (Au), silver (Ag), aluminum (Al), molybdenum (Mo), chromium (Cr), titanium (Ti), nickel (Ni), neodymium (Nd), and copper (Cu).

The inter-insulating layer ILD may cover the gate pattern GAT and may include an insulating material. In an embodiment, the inter-insulating layer ILD may include at least one of polysiloxane, silicon nitride, silicon oxide, and silicon oxynitride.

The first source-drain pattern SD1 may be disposed on the inter-insulating layer ILD, and at least a portion of the first source-drain pattern SD1 may be electrically connected to the semiconductor pattern SM. The first source-drain pattern SD1 may include a metal material. In an embodiment, the first source-drain pattern SD1 may include at least one of gold (Au), silver (Ag), aluminum (Al), molybdenum (Mo), chromium (Cr), titanium (Ti), nickel (Ni), neodymium (Nd), and copper (Cu).

The first via layer VIA1 may cover the first source-drain pattern SD1. The second source-drain pattern SD2 may penetrate the first via layer VIA1 and contact the first source-drain pattern SD1. The second via layer VIA2 may cover at least a portion of the second source-drain pattern SD2.

The pixel defining layer PDL may be disposed on the second via layer VIA2. A light-emitting diode opening L-OP may be defined in the pixel defining layer PDL, and a light-emitting diode LD may be disposed in the light-emitting diode opening L-OP.

The light-emitting diodes LD may be disposed on the first via layer VIA1 and the second via layer VIA2. The light-emitting diodes LD may include an anode electrode AE, an emission layer EML, and a cathode electrode CE. The anode electrode AE may be electrically connected to the semiconductor pattern SM through the first source-drain pattern SD1 and the second source-drain pattern SD2. In an embodiment of the disclosure, the light-emitting diodes LD may be, but not limited to, an organic light-emitting diode (“OLED”).

The encapsulation layer CL may cover the light-emitting diodes LD to protect the light-emitting diodes LD from oxygen and moisture. The encapsulation layer CL may include a first encapsulation layer CL1, a second encapsulation layer CL2, and a third encapsulation layer CL3. In an embodiment, the encapsulation layer CL may include at least one of silicon oxide, silicon nitride, and silicon oxynitride.

Each of the first encapsulation layer CL1, the second encapsulation layer CL2, and the third encapsulation layer CL3 may include at least one of an organic material and an inorganic material. The first encapsulation layer CL1 may cover the cathode electrode CE. The second encapsulation layer CL2 may be disposed on the first encapsulation layer CL1. The third encapsulation layer CL3 may be disposed on the second encapsulation layer CL2.

In an embodiment of the disclosure, at least one of the first encapsulation layer CL1, the second encapsulation layer CL2, and the third encapsulation layer CL3 may be omitted. In another embodiment of the disclosure, the encapsulation layer CL may further include at least one additional layer including at least one of an organic material and an inorganic material.

The bending insulating layer BI may overlap the bending region BA. The bending insulating layer BI may include an insulating material. In an embodiment, the bending insulating layer BI may include at least one of polyacrylic compounds, polyimide compounds, fluorinated carbon compounds, and benzocyclobutene compounds.

The plurality of pads PD may be disposed on the pad region PA. The plurality of pads PD may transfer signals provided by the electrical component EP to the plurality of spider wirings SL1 to SLn. The electrical component EP may be electrically connected to the plurality of pads PD. The electrical component EP may provide signals for controlling the plurality of light-emitting diodes LD.

The electrical component EP may include at least one of a flexible printed circuit board (“FPCB”) and a driver chip. The driver chip may provide control signals for the light-emitting diodes LD and may include a plurality of thin-film transistors.

In an embodiment of the disclosure, the electrical component EP may be any of a chip on film (“COF”) structure, a chip on plastic (“COP”) structure, or a chip on glass (“COG”) structure. However, the electrical component EP is not limited to the aforementioned examples and may be any component configured to provide signals for controlling the plurality of light-emitting diodes LD.

The plurality of spider wirings SL1 to SLn may extend from the plurality of pads PD and may transfer signals from the electrical component EP to at least one of the first source-drain pattern SD1 and the gate pattern GAT. In an embodiment of the disclosure, at least one of the second source-drain pattern SD2, the second via layer VIA2, the pixel defining layer PDL, the encapsulation layer CL, and the bending insulating layer BI may be omitted.

FIG. 2D is an enlarged view of a portion AA of the display panel DP shown in FIG. 2A. FIG. 2E is a cross-sectional view of a section SC1 of the cover region CA taken along line II-II′ of FIG. 2A, and FIG. 2F is a cross-sectional view of a section SC2 of the pad region PA taken along line III-III′ of FIG. 2D.

Referring to FIGS. 2D to 2F, a plurality of first crack-prevention openings OP1 may be defined in a portion of the inter-insulating layer ILD overlapping the cover region CA, and a plurality of second crack-prevention openings OP2 may be defined in a portion of the inter-insulating layer ILD overlapping the pad region PA. Each of the first crack-prevention openings OP1 may extend along an outer edge of the cover region CA, and each of the second crack-prevention openings OP2 may extend along an outer edge of the pad region PA. The first crack-prevention openings OP1 and the second crack-prevention openings OP2 may function as crack dams to block the propagation of cracks.

In an embodiment of the disclosure, at least a portion of a shape formed by projecting each of the second crack-prevention openings OP2 and each of the second protruding members PT2 onto the base substrate BS may be a line shape.

The number of the first crack-prevention openings OP1 and the number of the second crack-prevention openings OP2 may differ from each other. In an embodiment, the number of the second crack-prevention openings OP2 may be greater than the number of the first crack-prevention openings OP1. Therefore, by the disclosure, it is possible to block crack propagation more effectively in the pad region PA than in the cover region CA.

In an embodiment of the disclosure, the plurality of second crack-prevention openings OP2 may be defined between the plurality of spider wirings SL1 to SLn and the outer edge BB of the pad region PA. Therefore, the second crack-prevention openings OP2 may block cracks propagating in the direction of the plurality of spider wirings SL1 to SLn from the outer edge BB of the pad region PA.

In an embodiment of the disclosure, the second crack-prevention openings OP2 may be spaced apart from the first crack-prevention openings OP1 across the bending region BA in a plan view. In an embodiment of the disclosure, when the bending region BA is bent, the second crack-prevention openings OP2 may overlap at least one of the first region AR1 and the cover region CA.

Referring to FIGS. 2D to 2F, in an embodiment of the disclosure, a portion of the inter-insulating layer ILD may be disposed to overlap the first region AR1 and may include a plurality of first protruding members PT1 and a plurality of second protruding members PT2. In an embodiment of the disclosure, the first protruding member PT1 may be disposed between two first crack-prevention openings next (adjacent) to each other among the plurality of first crack-prevention openings OP1, and the second protruding member PT2 may be disposed between two second crack-prevention openings next (adjacent) to each other among the plurality of second crack-prevention openings OP2.

The plurality of first protruding members PT1 may be arranged to be spaced apart from each other on the cover region CA, and the plurality of second protruding members PT2 may be arranged to be spaced apart from each other on the pad region PA. Each of the first protruding members PT1 may extend along at least a portion of an outer boundary of the cover region CA, and each of the second protruding members PT2 may extend along at least a portion of an outer boundary of the pad region PA.

In an embodiment of the disclosure, the number of the first protruding members PT1 and the number of the second protruding members PT2 may differ from each other. In an embodiment, the number of the second protruding members PT2 may be greater than the number of the first protruding members PT1. That is, the number of the second crack-prevention openings OP2 may be greater than the number of the first crack-prevention openings OP1.

In an embodiment of the disclosure, the second protruding members PT2 may be disposed between the plurality of spider wirings SL1 to SLn and the outer edge BB of the pad region PA. In an embodiment of the disclosure, the second protruding members PT2 may be spaced apart from the first protruding members PT1 across the bending region BA in a plan view. In an embodiment of the disclosure, when the bending region BA is bent, the second protruding members PT2 may overlap at least one of the first region AR1 and the cover region CA.

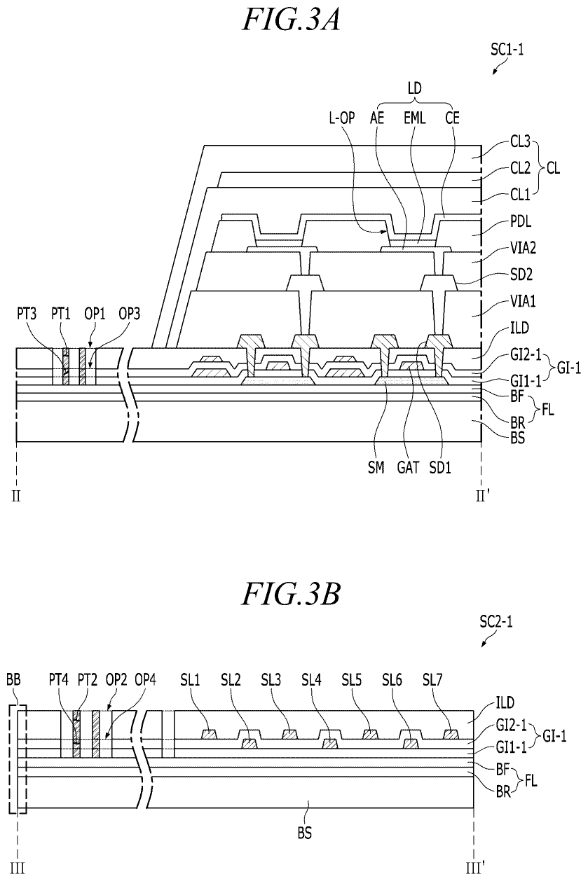

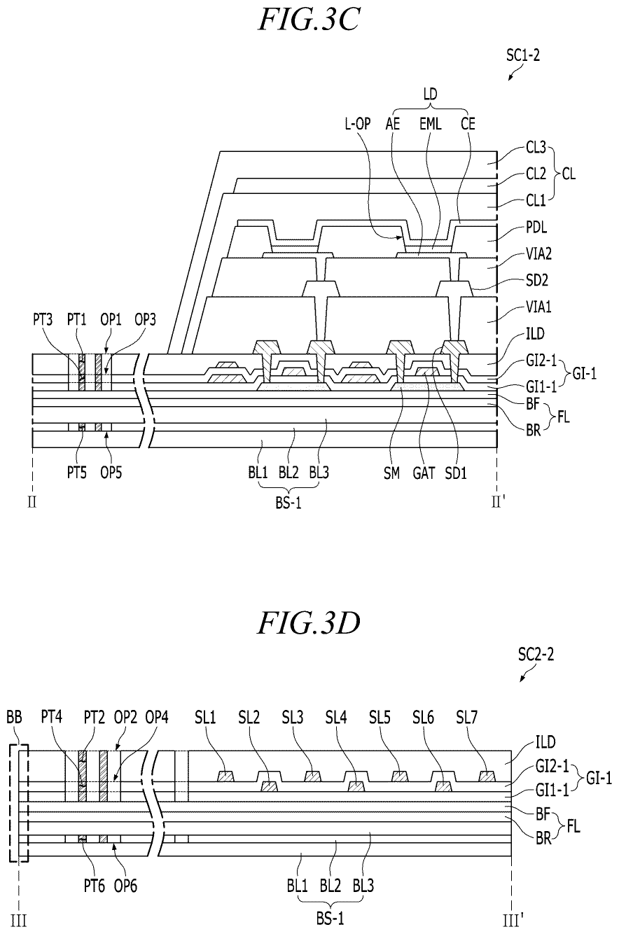

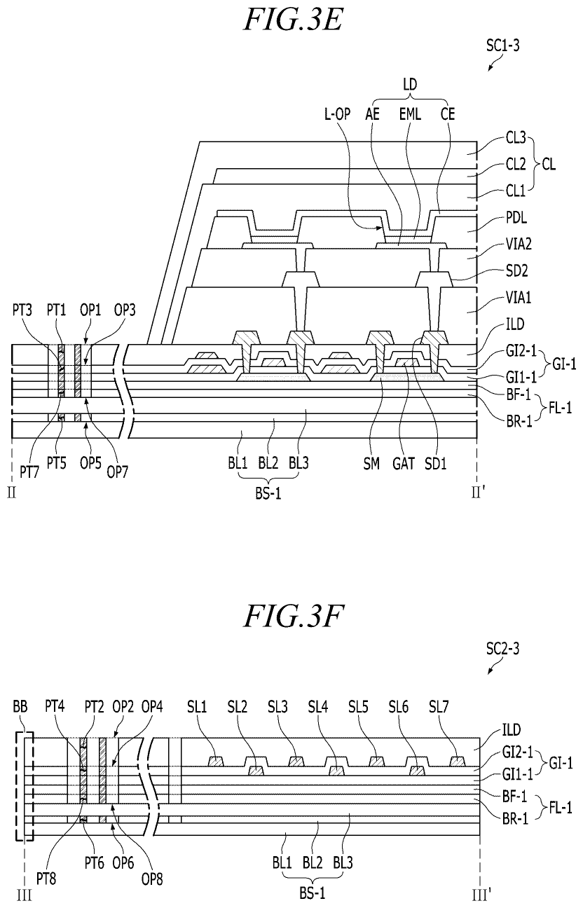

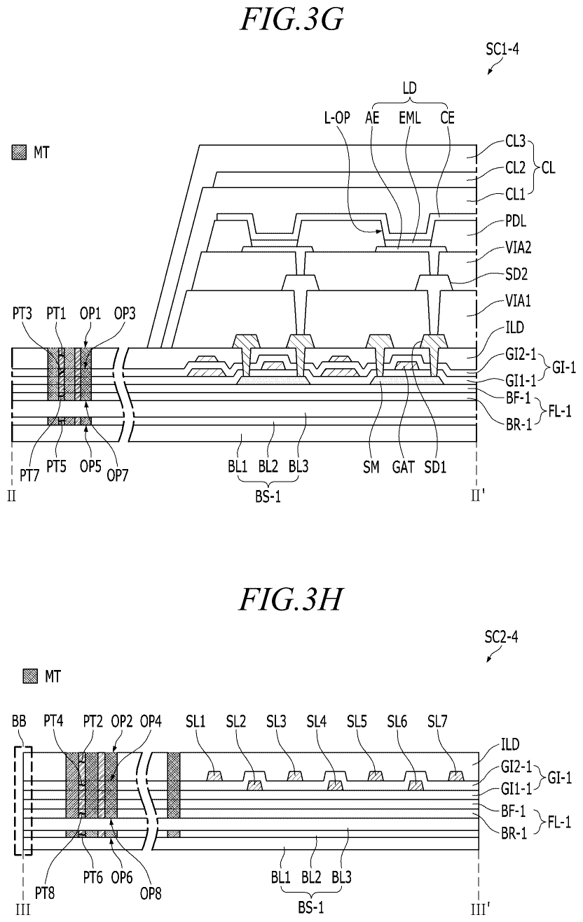

FIG. 3A is a cross-sectional view illustrating a section SC1-1 of the cover region CA taken along line II-II′ of FIG. 2A. 3B is a cross-sectional view illustrating a section SC2-1 of the pad region PA taken along line III-III′ of FIG. 2D.

Referring to FIGS. 3A and 3B, in an embodiment of the disclosure, a plurality of third crack-prevention openings OP3 and a plurality of fourth crack-prevention openings OP4 may be defined in the gate insulating layer GI-1 including a first gate insulating layer GI1-1 and a second gate insulating layer GI2-1. The plurality of third crack-prevention openings OP3 may, respectively, overlap the plurality of first crack-prevention openings OP1, and the plurality of fourth crack-prevention openings OP4 may, respectively, overlap the plurality of second crack-prevention openings OP2. The third crack-prevention openings OP3 and the fourth crack-prevention openings OP4 may function as crack dams configured to block the propagation of cracks.

In an embodiment of the disclosure, the gate insulating layer GI-1 may include a plurality of third protruding members PT3 and a plurality of fourth protruding members PT4. The plurality of third protruding members PT3 may, respectively, overlap the plurality of first protruding members PT1, and the plurality of fourth protruding members PT4 may, respectively, overlap the plurality of second protruding members PT2.

In an embodiment of the disclosure, the third protruding member PT3 may be disposed between two third crack-prevention openings next (adjacent) to each other among the plurality of third crack-prevention openings OP3, and the fourth protruding member PT4 may be disposed between two fourth crack-prevention openings next (adjacent) to each other among the plurality of fourth crack-prevention openings OP4.

FIG. 3C is a cross-sectional view illustrating a section SC1-2 of the cover region CA taken along line II-II′ of FIG. 2A. FIG. 3D is a cross-sectional view illustrating a section SC2-2 of the pad region PA taken along line III-III′ of FIG. 2D.

In an embodiment of the disclosure, the base substrate BS-1 may include a first base layer BL1, a second base layer BL2, and a third base layer BL3. The first base layer BL1 may include an organic material. The second base layer BL2 may be disposed on the first base layer BL1 and may include an inorganic material. The third base layer BL3 may be disposed on the second base layer BL2 and may include an organic material.

Referring to FIGS. 3C and 3D, in an embodiment of the disclosure, at least one of a plurality of fifth crack-prevention openings OP5 and a plurality of sixth crack-prevention openings OP6 may be defined in the second base layer BL2. The plurality of fifth crack-prevention openings OP5 may, respectively, overlap the plurality of first crack-prevention openings OP1, and the plurality of sixth crack-prevention openings OP6 may, respectively, overlap the plurality of second crack-prevention openings OP2. The fifth crack-prevention openings OP5 and the sixth crack-prevention openings OP6 may function as crack dams configured to block the propagation of cracks.

In an embodiment of the disclosure, the second base layer BL2 may include a plurality of fifth protruding members PT5 and a plurality of sixth protruding members PT6. The plurality of fifth protruding members PT5 may, respectively, overlap the plurality of first protruding members PT1, and the plurality of sixth protruding members PT6 may, respectively, overlap the plurality of second protruding members PT2.

In an embodiment of the disclosure, the fifth protruding member PT5 may be disposed between two fifth crack-prevention openings next (adjacent) to each other among the plurality of fifth crack-prevention openings OP5, and the sixth protruding member PT6 may be disposed between two sixth crack-prevention openings next (adjacent) to each other among the plurality of sixth crack-prevention openings OP6.

FIG. 3E is a cross-sectional view illustrating a section SC1-3 of the cover region CA taken along line II-II′ of FIG. 2A. FIG. 3F is a cross-sectional view illustrating a section SC2-3 of the pad region PA taken along line III-III′ of FIG. 2D.

Referring to FIGS. 3E and 3F, in an embodiment of the disclosure, at least one of a plurality of seventh crack-prevention openings OP7 and a plurality of eighth crack-prevention openings OP8 may be defined in the functional layer FL-1 including a barrier layer BR-1 and a buffer layer BF-1. The plurality of seventh crack-prevention openings OP7 may, respectively, overlap the plurality of first crack-prevention openings OP1, and the plurality of eighth crack-prevention openings OP8 may, respectively, overlap the plurality of second crack-prevention openings OP2. The seventh crack-prevention openings OP7 and the eighth crack-prevention openings OP8 may function as crack dams configured to block the propagation of cracks.

In an embodiment of the disclosure, the functional layer FL-1 may include a plurality of seventh protruding members PT7 and a plurality of eighth protruding members PT8. The plurality of seventh protruding members PT7 may, respectively, overlap the plurality of first protruding members PT1, and the plurality of eighth protruding members PT8 may, respectively, overlap the plurality of second protruding members PT2.

In an embodiment of the disclosure, the seventh protruding member PT7 may be disposed between two seventh crack-prevention openings next (adjacent) to each other among the plurality of seventh crack-prevention openings OP7, and the eighth protruding member PT8 may be disposed between two eighth crack-prevention openings next (adjacent) to each other among the plurality of eighth crack-prevention openings OP8.

FIG. 3G is a cross-sectional view illustrating a section SC1-4 of the cover region CA taken along line II-II′ of FIG. 2A. FIG. 3H is a cross-sectional view illustrating a section SC2-4 of the pad region PA taken along line III-III′ of FIG. 2D.

Referring to FIGS. 3G and 3H, in an embodiment of the disclosure, a predetermined material MT may be disposed in at least one of the plurality of first crack-prevention openings OP1, the plurality of second crack-prevention openings OP2, the plurality of third crack-prevention openings OP3, the plurality of fourth crack-prevention openings OP4, the plurality of fifth crack-prevention openings OP5, the plurality of sixth crack-prevention openings OP6, the plurality of seventh crack-prevention openings OP7, and the plurality of eighth crack-prevention openings OP8. In an embodiment, the predetermined material MT may be an organic material.

In a predetermined layer, an area including or consisting of the organic material may have a lower hardness compared to an area including or consisting of an inorganic material and may effectively absorb tensile stress caused by bending. Therefore, when the predetermined material MT, which is an organic material, is disposed in the crack-prevention openings, it is possible to block the propagation of cracks more effectively.

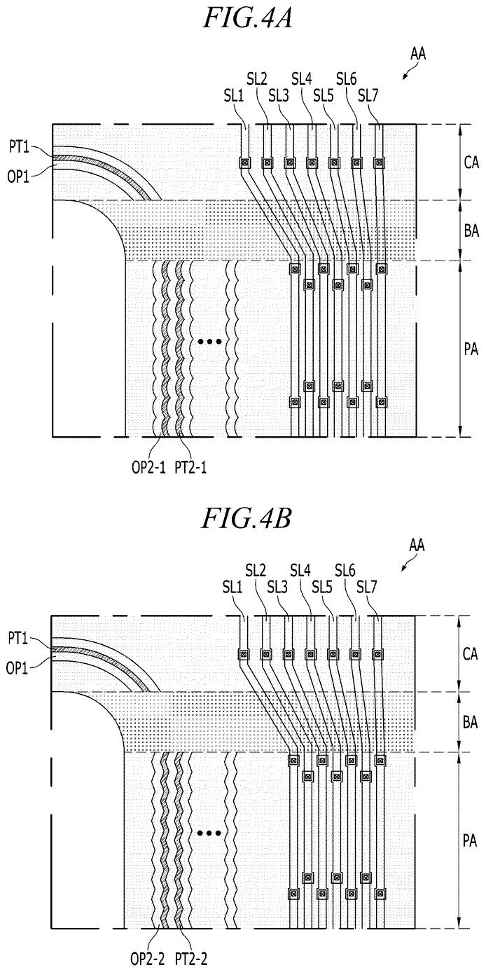

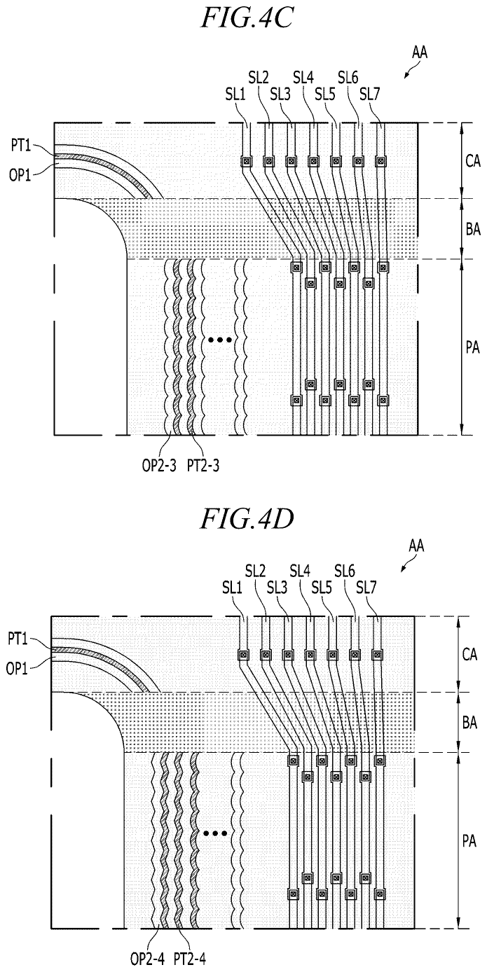

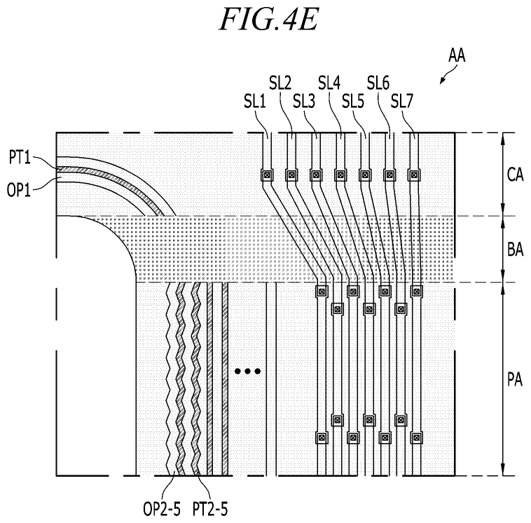

FIGS. 4A to 4E are enlarged views of a portion AA of the second region AR2 shown in FIG. 2A.

In an embodiment of the disclosure, the shape formed by projecting each of the second crack-prevention openings OP2 and each of the second protruding members PT2 onto the base substrate BS may include at least one of a line shape, a curve shape, and a zigzag shape.

Referring to FIG. 4A, the shape formed by projecting each of the second crack-prevention openings OP2-1 onto the base substrate BS may include a curve shape. The shape formed by projecting each of the second protruding members PT2-1 onto the base substrate BS may also include a curve shape. In an embodiment of the disclosure, the curve shape may be a repeated arc or elliptical arc.

Referring to FIG. 4B, the shape formed by projecting each of the second crack-prevention openings OP2-2 onto the base substrate BS may include a zigzag shape. The shape formed by projecting each of the second protruding members PT2-2 onto the base substrate BS may also include a zigzag shape.

Referring to FIG. 4C, the shape formed by projecting some of the second crack-prevention openings OP2-3 onto the base substrate BS may include a line shape, while the shape formed by projecting remaining (the other) second crack-prevention openings OP2-3 onto the base substrate BS may include a curve shape. In an embodiment of the disclosure, the arrangement of the second crack-prevention openings OP2-3 having line shapes and those having curve shapes may be freely adjusted.

Referring to FIG. 4C, the shape formed by projecting some of the second protruding members PT2-3 onto the base substrate BS may include a line shape, while the shape formed by projecting remaining (the other) second protruding members PT2-3 onto the base substrate BS may include a curve shape. In an embodiment, the arrangement of the second protruding members PT2-3 having line shapes and those having curve shapes may also be freely adjusted.

Referring to FIG. 4D, the shape formed by projecting some of the second crack-prevention openings OP2-4 onto the base substrate BS may include a zigzag shape, while the shape formed by projecting remaining (the other) second crack-prevention openings OP2-4 onto the base substrate BS may include a curve shape. In an embodiment, the arrangement of the second crack-prevention openings OP2-4 having zigzag shapes and those having curve shapes may be freely adjusted.

Referring to FIG. 4D, the shape formed by projecting some of the second protruding members PT2-4 onto the base substrate BS may include a zigzag shape, while the shape formed by projecting remaining (the other) second protruding members PT2-4 onto the base substrate BS may include a curve shape. In an embodiment, the arrangement of the second protruding members PT2-4 having zigzag shapes and those having curve shapes may be freely adjusted.

Referring to FIG. 4E, the shape formed by projecting some of the second crack-prevention openings OP2-5 onto the base substrate BS may include a zigzag shape, while the shape formed by projecting remaining (the other) second crack-prevention openings OP2-5 onto the base substrate BS may include a line shape. In an embodiment, the arrangement of the second crack-prevention openings OP2-5 having zigzag shapes and those having line shapes may be freely adjusted.

Referring to FIG. 4E, the shape formed by projecting some of the second protruding members PT2-5 onto the base substrate BS may include a zigzag shape, while the shape formed by projecting remaining (the other) second protruding members PT2-5 onto the base substrate BS may include a line shape. In an embodiment, the arrangement of the second protruding members PT2-5 having zigzag shapes and those having line shapes may also be freely adjusted.

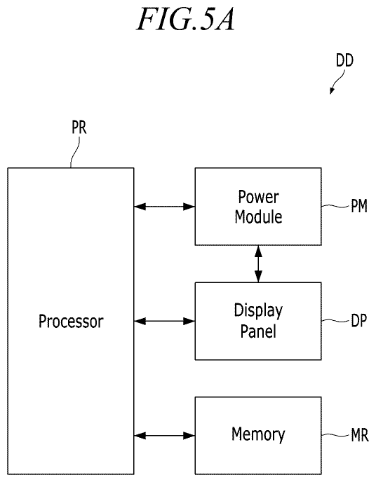

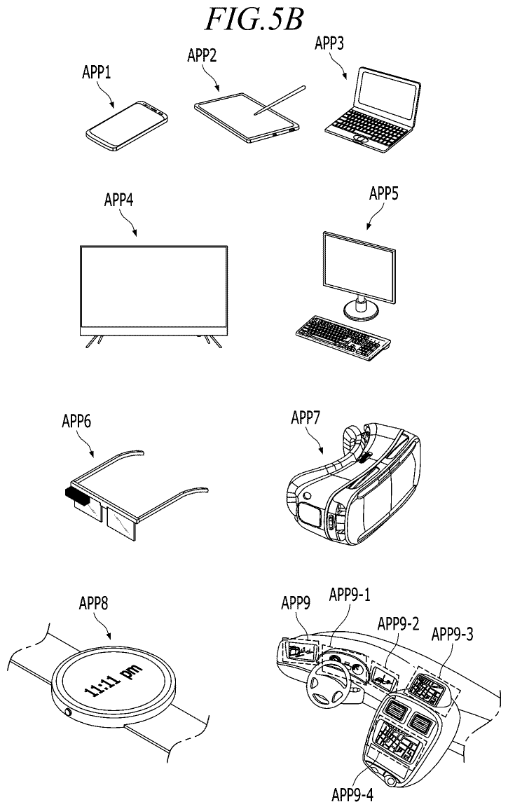

FIG. 5A illustrates a block diagram of an embodiment of an electronic device DD according to the disclosure.

Referring to FIG. 5A, the electronic device DD in an embodiment may include a display panel DP, a processor PR, a memory MR, and a power module PM. The processor PR may include at least one of a central processing unit (“CPU”), an application processor (“AP”), a graphic processing unit (“GPU”), a communication processor (“CP”), an image signal processor (“ISP”), and a controller.

The memory MR may have data and information desired for the operations of the processor PR or the display panel DP stored therein. When the processor PR executes an application stored in the memory MR, image data signals and/or input control signals may be transmitted to the display panel DP, which may then process the received signals and output visual information through the display screen.

The power module PM may include a power supply module, such as a power adapter or a battery device, and a power conversion module configured to convert the power supplied by the power supply module to generate the power desired for the operation of the electronic device DD.

At least one of the components of the electronic device DD described above may be included in a display device in the embodiments described above. Additionally, some individual modules included within a single functional module may be integrated into the display device, while others may be provided separately from the display device. In an embodiment, the display device may include the display panel DP, while the processor PR, the memory MR, and the power module PM may be provided as separate devices within the electronic device DD.

FIG. 5B illustrates an embodiment of various electronic devices DD according to the disclosure.

Referring to FIG. 5B, the display panel DP in the embodiments of the disclosure may be applied to various electronic devices DD, such as an image display electronic device including a smartphone APP1, a tablet PC APP2, a laptop computer APP3, a television (“TV”) APP4, or a desktop monitor APP5. The display panel DP may also be included in wearable electronic devices, such as smart glasses APP6, a head-mounted display APP7, or a smartwatch APP8. Additionally, the display panel DP may be included in vehicle-mounted electronic devices APP9 to APP9-4, such as a center information display (“CID”), an instrument panel, a center fascia, a dashboard, or a rear-view mirror display.

While illustrative embodiments of the disclosure have been described above, anyone ordinarily skilled in the art to which the disclosure pertains shall appreciate that there may be a variety of modifications and permutations of the disclosure without departing from the technical ideas and scopes of the disclosure that are defined in the appended claims. Moreover, it shall be appreciated that the disclosed embodiments are not intended to restrict the disclosure thereto and that every technical idea within the appended claims and their equivalents is interpreted to be included in the scope of the disclosure.

What is claimed is:

1. A display panel comprising:
a base substrate including:
a first region; and
a second region comprising:
a bending region which is bendable;
a cover region extending from one side of the bending region and surrounding the first region; and
a pad region extending from an opposite side of the bending region opposite to the one side of the bending region;
a semiconductor pattern disposed on the first region and comprising a semiconductor material;
a gate insulating layer disposed on the base substrate and covering the semiconductor pattern;
a gate pattern disposed on the gate insulating layer and comprising at least a portion overlapping the semiconductor pattern;
an inter-insulating layer covering the gate pattern;
a source-drain pattern disposed on the inter-insulating layer and comprising at least a portion electrically connected to the semiconductor pattern;
a via layer covering the source-drain pattern; and
a light-emitting diode disposed on the via layer,
wherein a plurality of first crack-prevention openings, each extending along an outer edge of the cover region, is defined in a portion of the inter-insulating layer overlapping the cover region,
a plurality of second crack-prevention openings, each extending along an outer edge of the pad region, is defined in a portion of the inter-insulating layer overlapping the pad region, and
a number of the plurality of first crack-prevention openings and a number of the plurality of second crack-prevention openings are different from each other.

2. The display panel of claim 1, wherein the number of the plurality of second crack-prevention openings is greater than the number of the plurality of first crack-prevention openings.

3. The display panel of claim 2, wherein at least one of a plurality of third crack-prevention openings and a plurality of fourth crack-prevention openings is defined in the gate insulating layer, wherein the plurality of third crack-prevention openings overlaps the plurality of first crack-prevention openings, respectively, and the plurality of fourth crack-prevention openings overlaps the plurality of second crack-prevention openings, respectively.

4. The display panel of claim 3, further comprising:
a plurality of pads disposed on the pad region;
an electrical component overlapping the plurality of pads; and
a plurality of spider wirings, each extending from the plurality of pads and configured to transfer signals provided by the electrical component to at least one of the source-drain pattern and the gate pattern,
wherein the plurality of second crack-prevention openings is defined between the plurality of spider wirings and the outer edge of the pad region.

5. The display panel of claim 4, wherein the plurality of second crack-prevention openings is spaced apart from the plurality of first crack-prevention openings across the bending region in a plan view.

6. The display panel of claim 4, wherein, when the bending region is bent, the plurality of second crack-prevention openings overlaps at least one of the first region and the cover region.

7. The display panel of claim 4, wherein the base substrate comprises:
a first base layer comprising an organic material;
a second base layer disposed on the first base layer; and
a third base layer disposed on the second base layer and comprising an organic material,
at least one of a plurality of fifth crack-prevention openings and a plurality of sixth crack-prevention openings is defined in second base layer,
the plurality of fifth crack-prevention openings overlaps the plurality of first crack-prevention openings, respectively, and
the plurality of sixth crack-prevention openings overlaps the plurality of second crack-prevention openings, respectively.

8. The display panel of claim 4, wherein a shape formed by projecting each of the plurality of second crack-prevention openings onto the base substrate comprises at least one of a line shape, a curve shape, and a zigzag shape.

9. The display panel of claim 4, further comprising a functional layer disposed between the base substrate and the semiconductor pattern,
wherein at least one of a plurality of seventh crack-prevention openings and a plurality of eighth crack-prevention openings is defined in the functional layer,
the plurality of seventh crack-prevention openings overlaps the plurality of first crack-prevention openings, respectively, and
the plurality of eighth crack-prevention openings overlaps the plurality of second crack-prevention openings, respectively.

10. A display panel comprising:
a base substrate including:
a first region; and
a second region comprising:
a bending region which is bendable;
a cover region extending from one side of the bending region and surrounding the first region; and
a pad region extending from an opposite side of the bending region opposite to the one side of the bending region;
a semiconductor pattern disposed on the first region and comprising a semiconductor material;
a gate insulating layer disposed on the base substrate and covering the semiconductor pattern;
a gate pattern disposed on the gate insulating layer and comprising at least a portion overlapping the semiconductor pattern;
an inter-insulating layer covering the gate pattern and comprising:
a plurality of first protruding members spaced apart from each other on the cover region; and
a plurality of second protruding members spaced apart from each other on the pad region,
a source-drain pattern disposed on the inter-insulating layer comprising at least a portion electrically connected to the semiconductor pattern;
a via layer covering the source-drain pattern; and
a light-emitting diode disposed on the via layer,
wherein each of the first protruding members extends along at least a portion of an outer boundary of the cover region,
each of the second protruding members extends along at least a portion of an outer boundary of the pad region, and
a number of the first protruding members and a number of the second protruding members are different from each other.

11. The display panel of claim 10, wherein the number of the second protruding members is greater than the number of the first protruding members.

12. The display panel of claim 11, wherein the gate insulating layer comprises at least one of a plurality of third protruding members overlapping, respectively, the plurality of first protruding members and a plurality of fourth protruding members overlapping, respectively, the plurality of second protruding members.

13. The display panel of claim 12, further comprising:
a plurality of pads disposed on the pad region;
an electrical component electrically connected to the plurality of pads; and
a plurality of spider wirings, each extending from the plurality of pads and configured to transfer signals provided by the electrical component to at least one of the source-drain pattern and the gate pattern,
wherein the plurality of second protruding members is arranged between the plurality of spider wirings and an outer edge of the pad region.

14. The display panel of claim 13, wherein the plurality of second protruding members is spaced apart from the plurality of first protruding members across the bending region in a plan view.

15. The display panel of claim 13, wherein, when the bending region is bent, the plurality of second protruding members overlaps at least one of the first region and the cover region.

16. The display panel of claim 13, wherein the base substrate comprises:
a first base layer comprising an organic material;
a second base layer disposed on the first base layer and comprising at least one of a plurality of fifth protruding members overlapping, respectively, the plurality of first protruding members and a plurality of sixth protruding members overlapping, respectively, the plurality of second protruding members; and
a third base layer disposed on the second base layer and comprising an organic material.

17. The display panel of claim 13, wherein a shape formed by projecting each of the plurality of second protruding members onto the base substrate comprises at least one of a line shape, a curve shape, and a zigzag shape.

18. The display panel of claim 13, further comprising a functional layer disposed between the base substrate and the semiconductor pattern,
wherein the functional layer comprises at least one of a plurality of seventh protruding members overlapping, respectively, the plurality of first protruding members and a plurality of eighth protruding members overlapping, respectively, the plurality of second protruding members.

19. An electronic device comprising:
a display panel comprising:
a base substrate including:
a first region; and
a second region comprising:
a bending region which is bendable;
a cover region extending from one side of the bending region and surrounding the first region; and
a pad region extending from an opposite side of the bending region opposite to the one side of the bending region;
a semiconductor pattern disposed on the first region and comprising a semiconductor material;
a gate insulating layer disposed on the base substrate and covering the semiconductor pattern;
a gate pattern disposed on the gate insulating layer including at least a portion overlapping the semiconductor pattern;
an inter-insulating layer covering the gate pattern and comprising:
a plurality of first protruding members spaced apart from each other on the cover region; and
a plurality of second protruding members spaced apart from each other on the pad region;
a source-drain pattern disposed on the inter-insulating layer and comprising at least a portion electrically connected to the semiconductor pattern;
a via layer covering the source-drain pattern; and
a light-emitting diode disposed on the via layer,
wherein each of the first protruding members extends along at least a portion of an outer boundary of the cover region,
each of the second protruding members extends along at least a portion of an outer boundary of the pad region, and
a number of the first protruding members and a number of the second protruding members are different from each other.

20. The electronic device of claim 19, wherein a plurality of first crack-prevention openings, each extending along an outer edge of the cover region, is defined in a portion of the inter-insulating layer overlapping the cover region,
wherein a plurality of second crack-prevention openings, each extending along an outer edge of the pad region, is defined in a portion of the inter-insulating layer overlapping the pad region,
wherein each of the plurality of first protruding members is disposed between two first crack-prevention openings next to each other among the plurality of first crack-prevention openings, and
wherein each of the plurality of second protruding members is disposed between two second crack-prevention openings next to each other among the plurality of second crack-prevention openings.
